(19) United States
(12) Patent Application Publication
(10) Pub. No.: US 2025/0340177 A1
(43) Pub. Date: Nov. 6, 2025

(54) LOW VOLTAGE BATTERY HEALTH MONITORING OR MAINTENANCE

(71) Applicant: Rivian IP Holdings, LLC, Irvine, CA (US)

(72) Inventors: Kyle LOBO, Westchester, CA (US); Sanjeewa Keven SUGATAPALA, Long Beach, CA (US); Carl James TROVALL, Long Beach, CA (US); Long Phi HUYNH, Brea, CA (US); Steven HANG, Long Beach, CA (US); Ajay KUMAR, Phoenix, AZ (US); Glenn Morris FEINBERG, Carlsbad, CA (US); Mirisage Niral Sachinthana FERNANDO, Lake Forest, CA (US)

(21) Appl. No.: 19/059,043

(22) Filed: Feb. 20, 2025

Related U.S. Application Data
(60) Provisional application No. 63/642,587, filed on May 3, 2024.

(51) Int. Cl. B60R 16/033; B60R 16/023; H02J 7/00

(52) U.S. Cl. CPC B60R 16/033; B60R 16/0239; H02J 7/00302; H02J 7/005; H02J 7/0063

(57) ABSTRACT

A system for monitoring or managing a low voltage (LV) battery in an electric vehicle may include a ground busbar connected with a negative terminal of the LV battery and a negative temperature coefficient (NTC) sensor. An electronic control unit (ECU) may receive temperature data from the NTC sensor and voltage measurements via dedicated sense wires to monitor battery health. The system includes a bidirectional (BiDi) switch connected between the LV battery and a LV direct current with direct current converter (DCDC), enabling trickle charging during vehicle standby mode while preventing battery overcharging.

### CROSS REFERENCE TO RELATED APPLICATION(S)

The present application claims the benefit of U.S. Provisional Application No. 63/642,587, entitled “LOW VOLTAGE BATTERY HEALTH MONITORING BY ELECTRONIC CONTROL UNIT FOR ELECTRIC VEHICLES”, filed May 3, 2024, the entirety of which is incorporated herein for reference.

### INTRODUCTION

This application is directed to systems for monitoring or maintaining battery health.

### SUMMARY

A system for monitoring or maintaining battery health in an electric vehicle may implement temperature and voltage sensing through integration with electronic control units (ECUs). The system may include a ground busbar connected to a negative terminal of a low voltage battery and may incorporate a negative temperature coefficient (NTC) sensor. In some examples, a bidirectional switch may enable controlled charging during vehicle standby periods while minimizing battery cycling. The disclosed subject matter may reduce or eliminate the need for dedicated electronic control units by integrating discrete sensors monitored by a zonal controller.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates an example battery system with health sensing.

FIG. 2 illustrates an example block diagram of a battery system with health sensing.

FIG. 3 illustrates an example top view of a battery system that includes components of the battery system of FIG. 2.

FIG. 4 illustrates an example perspective view of a battery system that includes components of the battery system of FIG. 2.

FIG. 5A illustrates an example system associated with float charging a low voltage battery.

FIG. 5B illustrates an example system that includes a bidirectional (BiDi) switch.

FIG. 5C illustrates an example circuit diagram of a BiDi switch.

FIG. 6A illustrates an example overhead view of a vehicle with zonal power distribution as described herein.

FIG. 6B illustrates an example side view of a vehicle with zonal power distribution as described herein.

FIG. 6C illustrates an example block diagram of a system with zonal power distribution as described herein.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

Electric vehicles may feature a low voltage (LV) battery (e.g., 12V battery). The health of the LV battery may include an indication of the state of charge of the LV battery. The health of the LV battery may help determine how likely one or more components of the electric vehicle may operate at different periods, such as how likely a vehicle may be able to support hazard lights, continued driving of the vehicle for a period, or operation of other electronic components when there is a crash or fault.

Monitoring LV battery health may require sensing the voltage, current, and temperature at the terminal. The disclosed system may allow for an ECU to monitor voltage at the terminal of the battery by a separate set of wires measuring differential voltage across the terminals. In addition, the ECU may monitor temperature of the LV battery by using an off the shelf integrated eyelet thermistor chip which may have epoxy potting.

On a system level, the utilization of distributed voltage, current, or temperature sensing may enable integration of health monitoring tasks into an ECU. The use of an ECU may eliminate the need for an auxiliary intelligent battery sensor (IBS) module. The elimination of the IBS as disclosed may save cost by leveraging existing circuits. In addition, utilization of an ECU as disclosed may allow for different implementation of battery health characterization programming that takes into account other factors or vehicle components. The disclosed subject matter may provide for low voltage battery health monitoring on ECUs which may be cost effective and may allow for relatively increased flexibility in integrating monitoring into some systems.

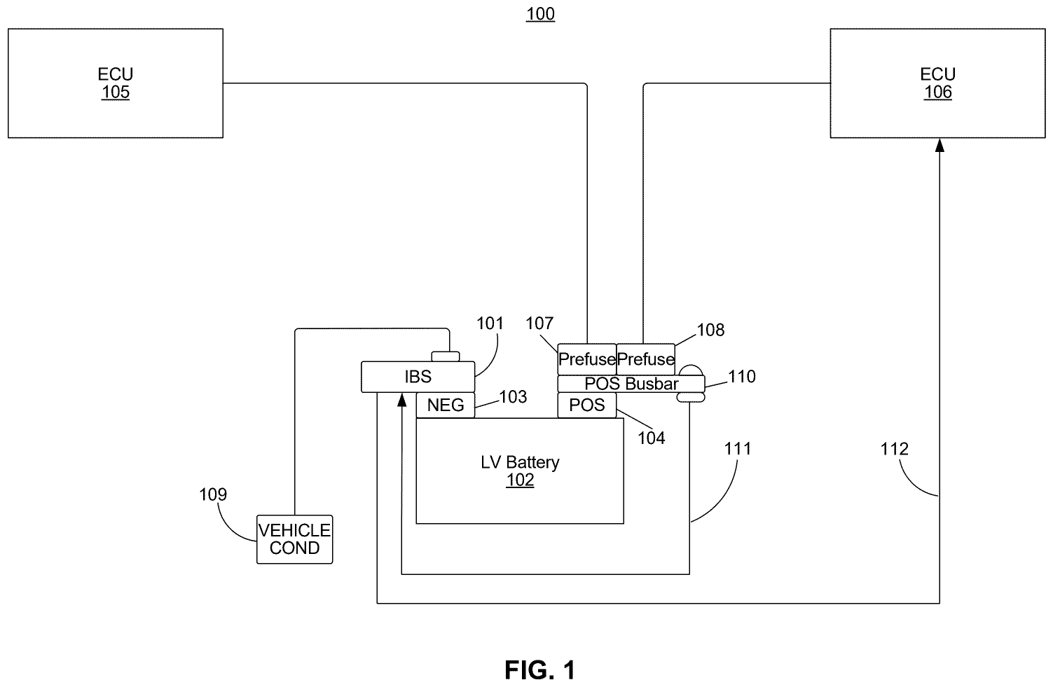

FIG. 1 illustrates an exemplary battery system 100 with health sensing. LV battery 102 may be a 12V battery. LV battery 102 may include negative terminal 103 and positive terminal 104. Intelligent battery system (IBS) 101 may be connected with negative terminal 103. In addition, IBS 101 may also be connected with vehicle chassis ground (CGND) 109, positive busbar 110 via voltage sense wire/supply+wire 111, and ECU 106 via communications link 112 (also referred herein as local interconnect network (LIN) or controller area network (CAN) 112). Positive busbar 110 may be connected with prefuse 107 for ECU 105 or prefuse 108 for ECU 106, which are respectively connected with ECU 105 and ECU 106.

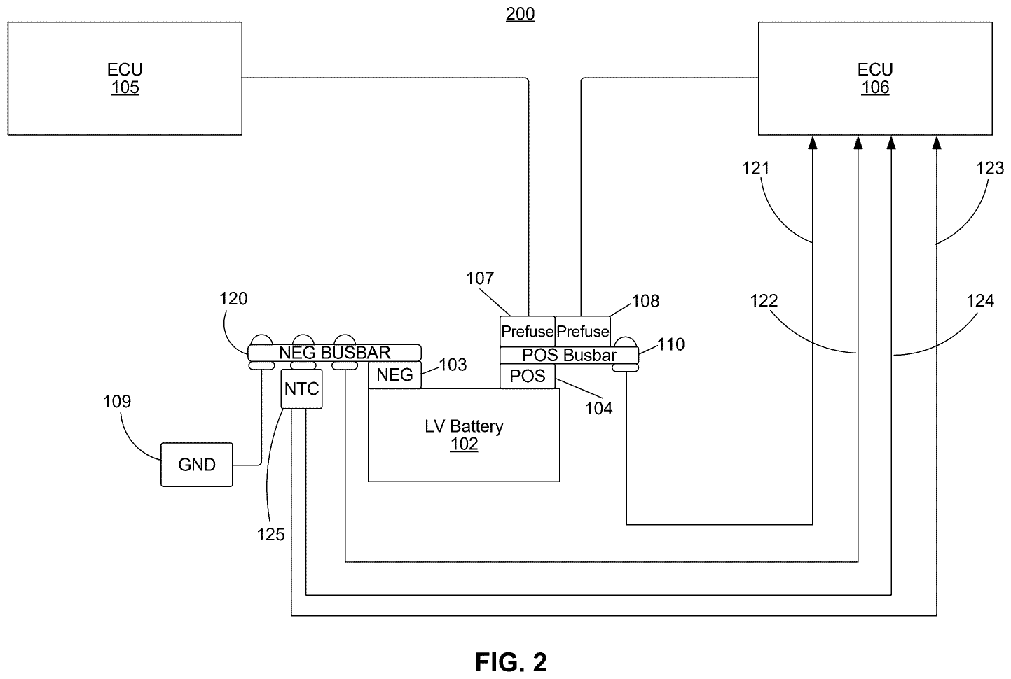

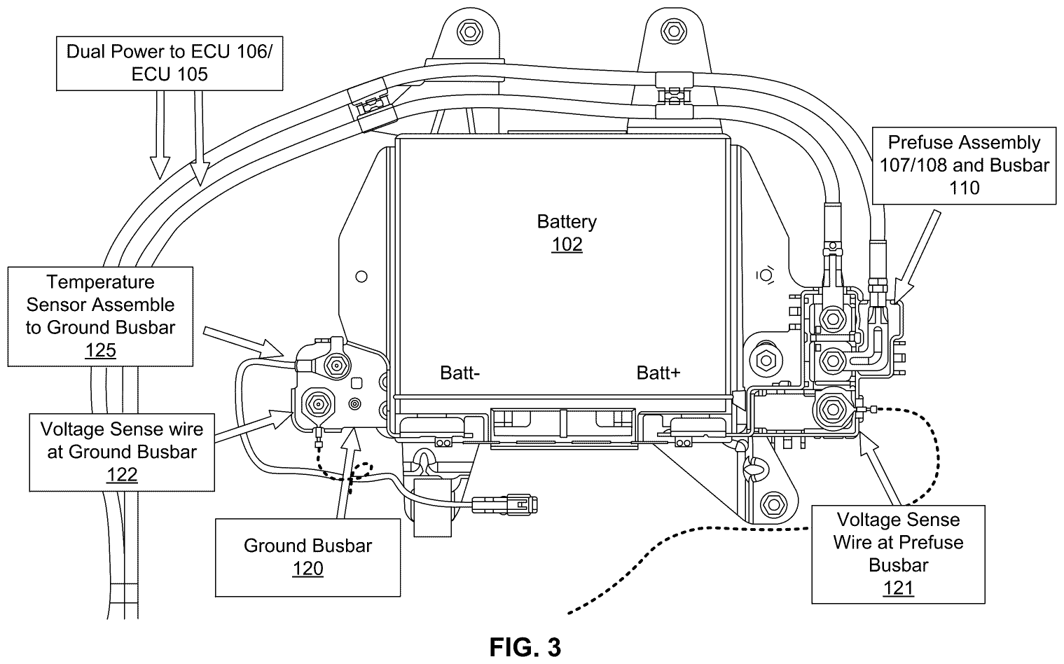

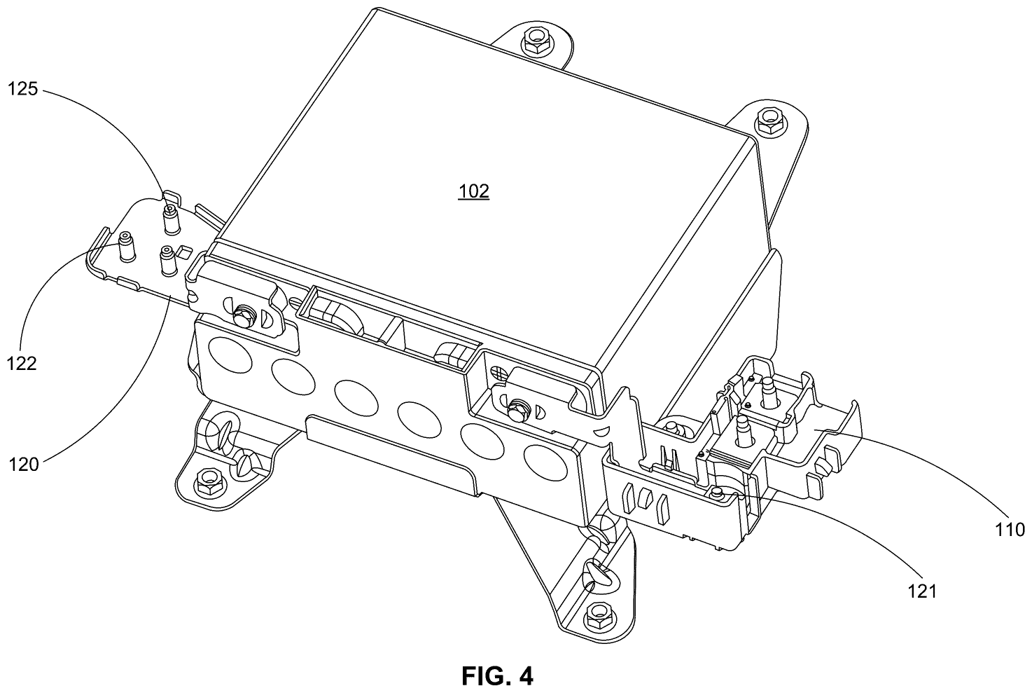

FIG. 2 illustrates an exemplary block diagram of a battery system 200 with health sensing. LV battery 102 may be a 12V battery. LV battery 102 may include negative terminal 103 and positive terminal 104. Negative busbar 120 (also referred herein as ground busbar) may be connected with negative terminal 103. In addition, negative busbar 120 may also be connected with vehicle CGND 109, negative temperature coefficient (NTC) temperature sensor 125, and ECU 106 via negative voltage sense wire 122. NTC temperature sensor 125 may be connected with ECU 106 via positive temperature sense wire 124 or negative temperature sense wire 123, as shown. Positive busbar 110 may be connected with prefuse 107 for ECU 105 or prefuse 108 for ECU 106, which are respectively connected with ECU 105 and ECU 106. Positive busbar 110 may be connected with ECU 106 via positive voltage sense wire 121. FIG. 3 illustrates an exemplary top view of a battery system that includes components of battery system 200. There may be dual redundant power to ECU 105 and ECU 106 as shown. FIG. 4 illustrates an exemplary perspective view of portions of battery system 200, which includes negative busbar 120.

The disclosed subject matter further provides for low voltage battery charging by an ECU (e.g., ECU 105 or ECU 106). The cycle life of a low voltage battery 102 (e.g., 12V battery 102) may have a significant impact on the performance of an electric vehicle, such as depleting the battery or accelerating the overall useful life of the battery. The disclosed subject matter provides a system that may allow for minimal cycles to LV battery 102 during standby (e.g., parked) and allow appropriate high current transient support.

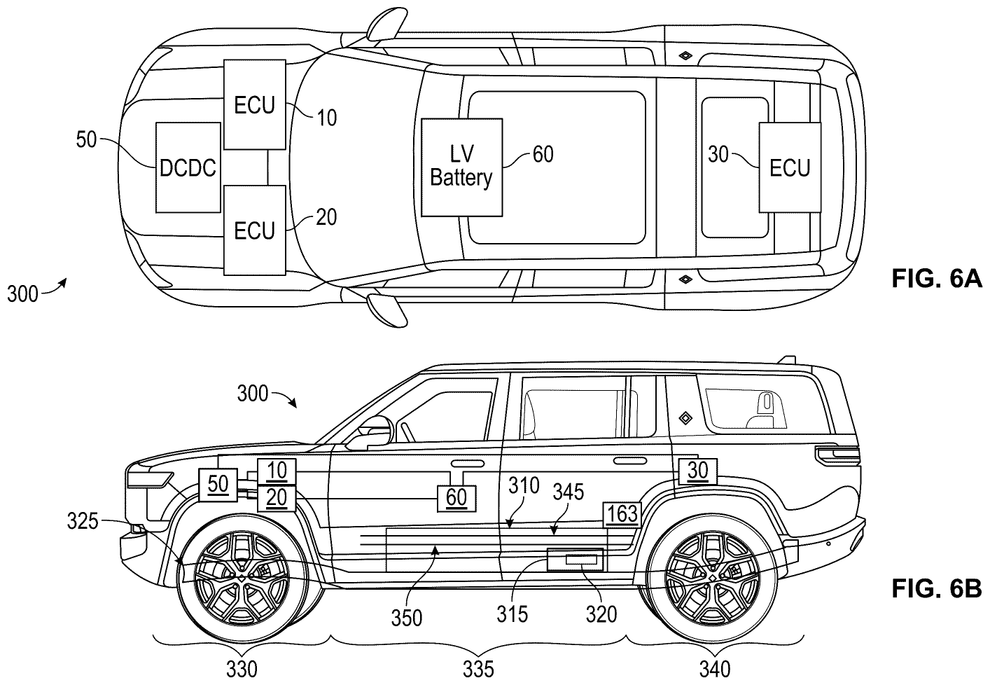

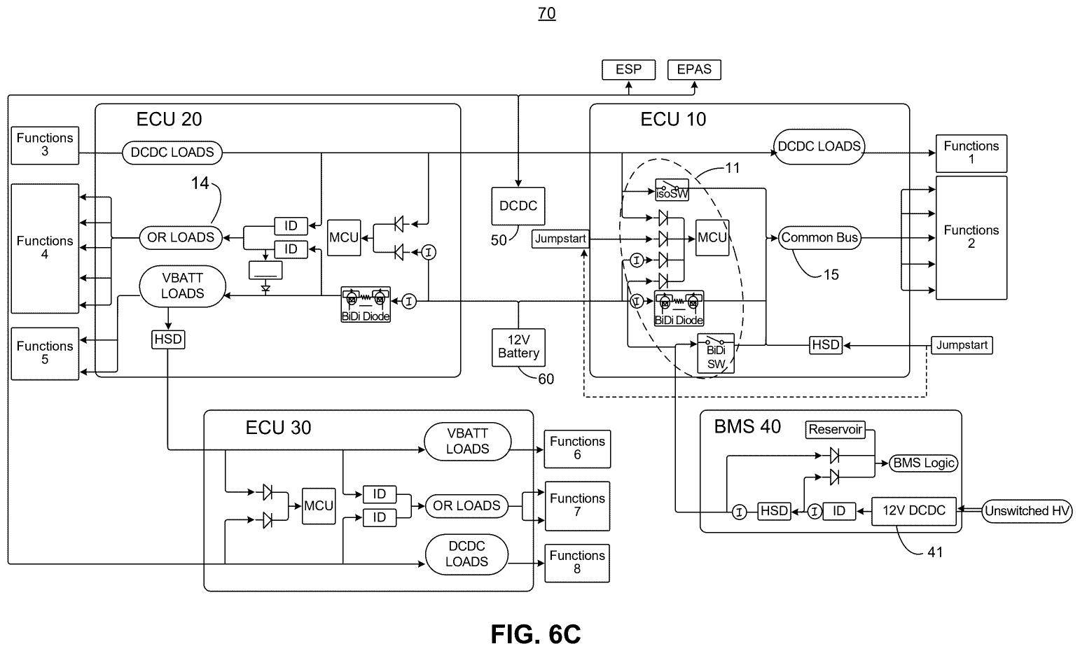

When parked there are vehicle electronics that may use power from LV battery 102 in short bursts or LV battery 102 may self-discharge at various temperatures. Ideally the voltage of LV battery 102 is not too high (e.g., above 13.7V, the battery may off gas) and not too low (e.g., at 12.8V the battery may cycle). In some scenarios when vehicle 300 of FIG. 6A is in standby, LV battery 102 may cycle every few hours. As disclosed in more detail herein, a back-to-back field-effect transistor (FET) circuit may be implemented that may allow one side of the pair of FETs to turn on and the other side to remain off. This allows conduction in for transients yet block current to the battery-preventing overcharge. The battery float may be kept charged by using a built in precharge feature of the FETs driver. As disclosed in more detail herein, the bus voltage may be biased to a higher voltage than LV battery 102 in order to bias draw from a standby power supply.

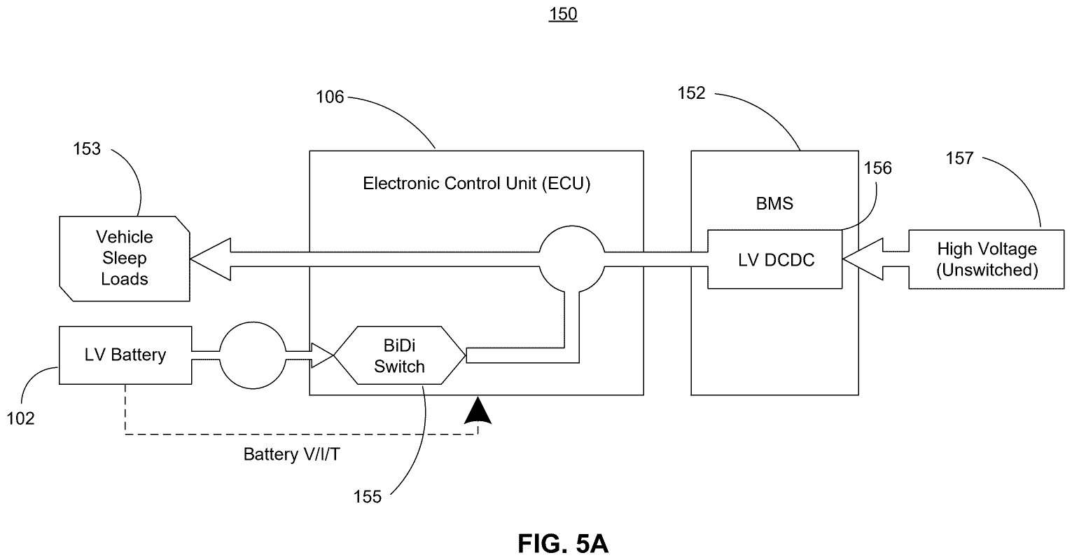

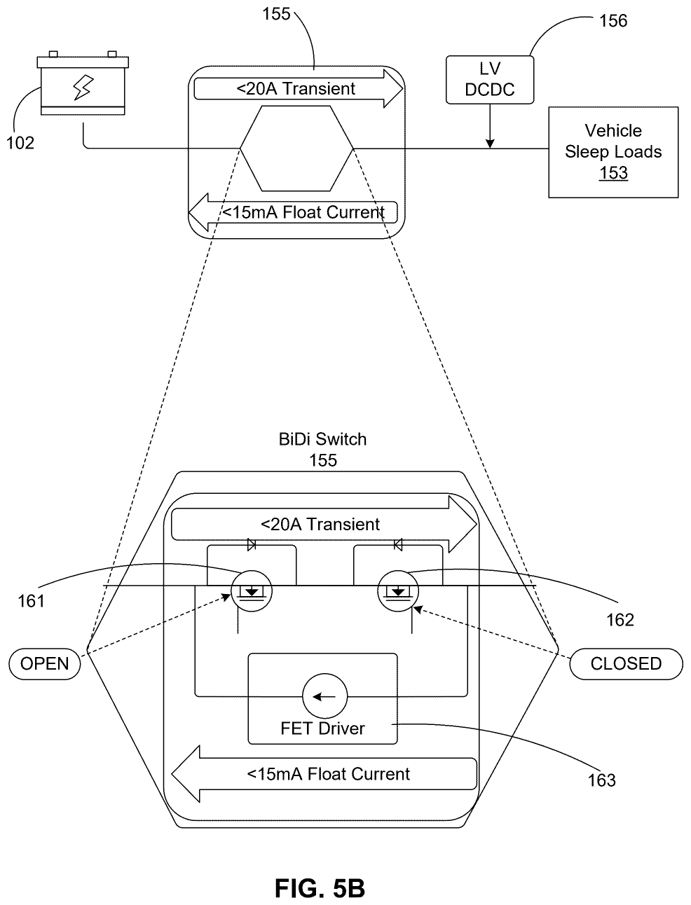

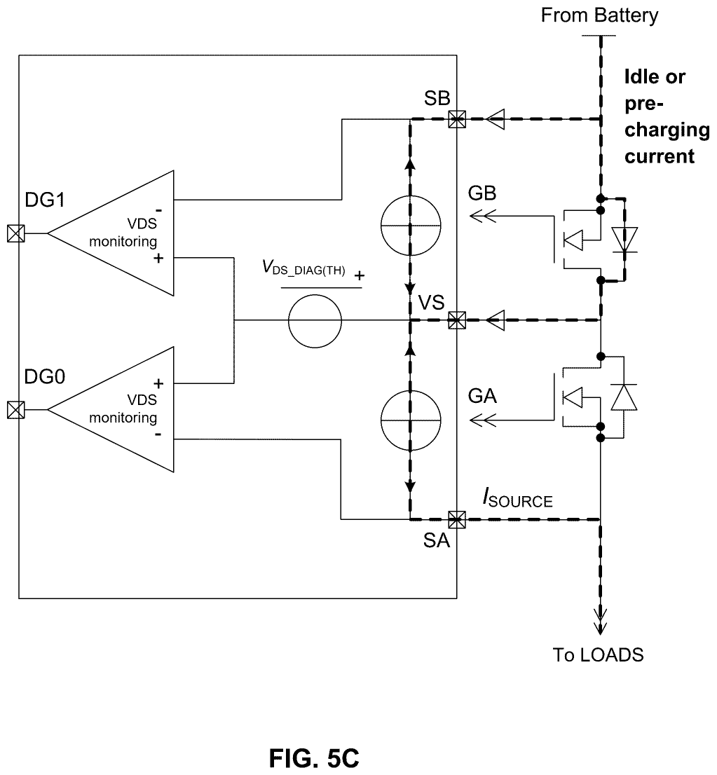

FIG. 5A illustrates an exemplary system 150 associated with float charging a low voltage battery. FIG. 5A shows exemplary power connections between ECU 106, battery management system (BMS) 152, high voltage (HV) battery pack 157, vehicle sleep loads 153, or LV battery 102 (e.g., 12V or 13V battery).

BMS 152 may include a LV direct current to direct current converter (DCDC) 156. LV DCDC 156 may be similar to a DCDC (e.g., DCDC 50 of FIG. 6A). The DCDC (also referred herein as the main DCDC) in electric vehicles (EVs) may step down the voltage of high voltage battery pack 157 so that vehicle electronics may be powered at a voltage within their operating range. The main DCDC, for example, may step down 450 V to approximately 14V and LV DCDC 156 may do so as well. A difference is that the main DCDC, for example, may support large load vehicle electronics, such as heaters, drive units, or the like. For example, the main DCDC may supply three kilowatts of power. Alternatively, LV DCDC 156 may be equipped to do much smaller loads (e.g., 30 watts, half a light bulb worth). LV DCDC 156 may also be significantly smaller in physical size than the main DCDC.

ECU 106 may include bidirectional (BiDi) switch 155. BiDi switch 155 during standby (also referred to herein as sleep or idle) mode for vehicle 300 may operate in a “diode mode” for transient or wake support.

FIG. 5B illustrates an exemplary system that includes BiDi switch 155. As shown, there may be an LV battery 102, LV DCDC 156, vehicle sleep loads 153, and BiDi switch 155. In this example, LV DCDC may bet set to supply at 14.5V while the LV battery 102 may be at 13V. BiDi switch 155 may be a chip that allows for metal-oxide-semiconductor field-effect transistors (MOSFETs) to be open or closed, which may help BiDi switch 155 to operate similar to a diode. When vehicle 300 is in a normal drive mode, MOSFET 161 and MOSFET 162 may be closed and power is transmitted through to one or more vehicle loads. When MOSFET 161 and MOSFET 162 are open and LV battery 102 is disconnected. When vehicle 300 is in a standby mode, MOSFET 161 may be in an open position and MOSFET 162 may be in a closed position, and therefore there may be just diode power for the transients (e.g., ECU wake-up from sleep or brake pedal application). During this standby mode, there is a trickle charge (e.g., <15 mA float current) for LV battery 102, which is a function of FET driver 163. BiDi switch 155 may be used in other operations for pre charging another circuit to prevent arcing and through testing it was found that BiDi switch 155 may allow a small amount of current to keep LV battery 102 float charged. FIG. 5C illustrates an exemplary circuit diagram of BiDi switch 155.

FIG. 6A illustrates an exemplary overhead view of vehicle 300. As further described herein, vehicle 300 may include electronic control units (ECUs) in front portion 330 of vehicle 300 (e.g., ECU 10 and ECU 20), an ECU in rear portion 340 of vehicle 300 (e.g., ECU 30), direct current to direct current converter (DCDC) 50, or low voltage (LV) battery 60 (e.g., 12V battery), among other things. ECU 10, ECU 20, or ECU 30 may be considered as zonal controllers.

FIG. 6B illustrates an exemplary side view of vehicle 300. As shown, the vehicle 300 may include one or more battery packs, such as high voltage (HV) battery pack 310 (e.g., 450V), which may be located near the center body portion 335 of vehicle 300. HV battery pack 310 may be coupled with one or more electrical systems of the vehicle 300 to provide power to the electrical systems. As further described herein, ECU 10 (e.g., ECU 106), ECU 20 (e.g., ECU 105), or ECU 30 may be communicatively connected with or have power distributed with each other and may be functionally redundant for power or other operations of electronic components of vehicle 300.

In one or more implementations, the vehicle 300 may be an electric vehicle having one or more electric motors that drive the wheels 302 of the vehicle using electric power from HV battery pack 310. In one or more implementations, the vehicle 300 may also, or alternatively, include one or more chemically-powered engines, such as a gas-powered engine or a fuel cell powered motor. For example, electric vehicles can be fully electric or partially electric (e.g., hybrid or plug-in hybrid). In various implementations, the vehicle 300 may be a fully autonomous vehicle that can navigate roadways without a human operator or driver, a partially autonomous vehicle that can navigate some roadways without a human operator or driver or that can navigate roadways with the supervision of a human operator, may be an unmanned vehicle that can navigate roadways or other pathways without any human occupants, or may be a human operated (non-autonomous) vehicle configured for a human operator.

In the example of FIG. 6B, the vehicle 300 may be implemented as a truck (e.g., a pickup truck) having a battery pack 310. As shown, HV battery pack 310 may include on or more battery modules 315, which may include one or more battery cells 320. However, this is merely illustrative and, in other implementations, HV battery pack 310 may be provided without any battery modules 315 (e.g., in a cell-to-pack configuration).

As shown in FIG. 6B, the vehicle 300 may include a support structure such as a chassis 325 (e.g., a frame, internal frame, or other support structure). The chassis 325 may support various components of the vehicle 300. As shown, the chassis 325 may span a front portion 330 (e.g., a hood or bonnet portion), center body portion 335, and a rear portion 340 (e.g., a trunk, payload, or boot portion) of the vehicle 300 in some implementations. In one or more implementations, HV battery pack 310 may be installed on the chassis 325 (e.g., within one or more of the front portion 330, center body portion 335, or the rear portion 340). As shown, HV battery pack 310 may include or be electrically coupled with one or more one busbars (e.g., one or more current collector elements). In the example of FIG. 6B, the vehicle 300 includes a first busbar 345 and a second busbar 350, either or both of which may include electrically conductive material to connect or otherwise electrically couple the battery module(s) 315 or the battery cell(s) s 320 with other electrical components of the vehicle 300 to provide electrical power to various systems or components of the vehicle 300.

In other implementations, the vehicle 300 may implemented as another type of electric truck, an electric delivery van, an electric automobile, an electric car, an electric motorcycle, an electric scooter, an electric passenger vehicle, an electric passenger or commercial truck, a hybrid vehicle, or other vehicles such as sea or air transport vehicles, planes, helicopters, submarines, boats, or drones, and/or any other movable apparatus having a battery pack 310 (e.g., that powers the propulsion or drive components of the moveable apparatus).

FIG. 6C illustrates an exemplary block diagram of system 70 that may include a plurality of ECUs of vehicle 300. An ECU is an embedded system that may control one or more of the electrical systems or subsystems in a vehicle. The positioning and connections of ECU 10, ECU 20, or ECU 30 may provide for a level of redundancy for faults, which may be caused by collisions or other malfunctions. The design of system 70 may allow vehicle 300 to safely operate for a period after the fault, such as being able to drive vehicle 300 (e.g., steer, brake, or accelerate) to a safe position off of a roadway or being able to operate electronic controlled functions (e.g., door latches) of vehicle 300, among other things. As shown, ECU 10, ECU 20, and ECU 30 may be connected with DCDC 50 (also referred herein as DCDC bus 50) to operate DCDC loads and a low voltage (LV) battery 60 (e.g., 12V battery or LV battery bus 60) to operate LV battery loads. In an example, one or more ECUs (e.g., ECU 10) may include a fault isolation system 11 (e.g., may include Bidi switch 155). In some configurations, in consideration of safety, only one ECU (e.g., ECU 10) may include fault isolation system 11. As shown, ECU 10 may include a common bus 15, which may operate slightly differently than other buses (e.g., OR load bus 14), as the common bus may allow for bidirectional power to be transmitted to and from LV battery 60 (e.g., LV battery 102) that may be a function of using fault isolation system 11. The common bus (specific to ECU 10) allows power to flow bidirectionally, from LV battery 60 to DCDC 50, or from DCDC 50 to LV battery 60. The OR bus does not allow power to flow bidirectionally (it does not connect or isolate LV battery 60 and DCDC 50 networks). The other element, which is a shared attribute of both common bus and OR Bus, that in the event of a failure of the DCDC 50 or LV battery 60, the common bus (or OR Bus) will retain operation (e.g., will be available).

With continued reference to FIG. 6C, each ECU may have on or more dedicated functions that may be powered by DCDC 50, LV battery 60, or LV DCDC 41. ECU 10 may operate functions 1, functions 2, and jumpstart functions. Functions 1 may include functions such as first row universal serial bus, or electronic stability program (ESP), among other things. Functions 2 may include functions such as right door latch, passenger seat motor, right headlamp, alarm module, or frunk latch, among other things. In this example, functions 1 of ECU 10 may only be powered by DCDC 50, while functions 2 of ECU 10 may be powered by DCDC 50 (which may be the primary power) or LV battery 60 (which may be the secondary power), which may be referred to common bus 15. ECU 10 may be located on the right front of vehicle 300 and therefore may operate functions primarily for the right portion of vehicle 300.

As shown in FIG. 6C, ECU 20 may operate functions 3, functions 4, and functions 5. Functions 3 may include functions such as front suspension valves, or autonomy control module, among other things. Functions 4 may include functions such as steering angle sensor, front wiper motor, left door latches, left headlamp, exterior near field communication (NFC), or on-board diagnostics (OBD) port, among other things. Functions 5 may include functions such as electric power assisted steering (EPAS), charge port door, interior NFC, or electric powered assisted breaking, among other things. In this example, functions 3 of ECU 20 may only be powered by DCDC 50 and functions 5 of ECU 20 may only be powered by LV battery 60. Functions 4 of ECU 20 may be powered by DCDC 50 (which may be the primary power) or LV battery 60 (which may be the secondary power), which may be referred to OR loads 14 (also referred herein as OR load bus 14). ECU 20 may be located on the left front of vehicle 300 and therefore may operate functions primarily for the left portion of vehicle 300.

As shown in FIG. 6C, ECU 30 may operate functions 6, functions 7, and functions 8. Functions 6 may include functions such as license plate lamp. Functions 7 may include functions such as rear vehicle access system sensors, liftgate latch, trailer brake, right lamp rear, or left lamp rear, among other things. Functions 8 may include functions such as right trailer brake lamp, or rear suspension valves, among other things. In this example, functions 8 of ECU 30 may only be powered by DCDC 50 and functions 6 of ECU 30 may only be powered by LV battery 60. Functions 7 of ECU 20 may be powered by DCDC 50 (which may be the primary power) or LV battery 60 (which may be the secondary power). ECU 20 may be located on the left front of vehicle 300 and therefore may operate functions primarily for the left portion of vehicle 300.

System 70 of FIG. 6C may include a battery management system (BMS) 40. BMS 40 (e.g., BMS 152) may be located at or near HV battery pack 310 of FIG. 6B, which LV DCDC 41 (e.g., LV DC 156) converts the HV DC to a lower voltage, such as 14V. LV DCDC 41 may help reduce the need for LV battery 60 for some operations, such as when vehicle 300 is in standby mode (e.g., parked). It is contemplated that the functions disclosed herein (e.g., functions 1 through functions 8) may be controlled by other ECUs or powered by any of the listed power sources.

The methods, systems, or apparatuses disclosed herein may be incorporated into electric vehicles or other devices. The methods, systems, or apparatuses disclosed herein may be incorporated into products, such as various feature specific electronic control units (ECUs). The disclosed subject matter may reduce or eliminate the need for dedicated electronic control units by integrating discrete sensors monitored by a zonal controller, such as ECU 10, ECU 20, or ECU 30.

Methods, systems, and apparatus for battery charging and monitoring in vehicles are disclosed herein. An apparatus may include a battery, a low voltage (LV) direct current to direct current converter (DCDC), and a bidirectional (BiDi) switch connected with the battery and the LV DCDC. The apparatus may include one or more vehicle loads. The BiDi switch may enable the battery to trickle charge when a vehicle is in a standby mode. The BiDi switch may include a field-effect transistor (FET) driver. The trickle charge may be for the battery and the trickle charge may be a function of the FET driver. The BiDi switch may include one or more field-effect transistors (FETs) that may be opened or closed. The FETs may include metal-oxide-semiconductor field-effect transistors (MOSFETs). Power may be transmitted from the battery to the vehicle loads when the first and second MOSFETs are closed, and the battery may be disconnected from transmitting power when both MOSFETs are open. A vehicle may include a low voltage battery operating at approximately 12 to 15 volts, a battery management system (BMS) which may include a LV DCDC, or an electronic control unit that may include a BiDi switch connected with the LV battery and LV DCDC. An apparatus may include a vehicle ground connection, a negative temperature coefficient (NTC) sensor, a negative voltage sensor connection, a negative terminal connection, or a ground busbar connected with these components. The NTC sensor may include negative and positive temperature sense connections with an electronic control unit. The apparatus may further include a low voltage battery, first and second prefuses connected with respective first and second electronic control units, and a positive busbar connected with the battery positive terminal and both prefuses. All combinations (including the removal or addition of components and connections) are contemplated in a manner consistent with the other portions of the detailed description.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

The predicate words “configured to”, “operable to”, and “programmed to” do not imply any particular tangible or intangible modification of a subject, but, rather, are intended to be used interchangeably. In one or more implementations, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

The word “exemplary” is used herein to mean “serving as an example, instance, or illustration”. Any embodiment described herein as “exemplary” or as an “example” is not necessarily to be construed as preferred or advantageous over other embodiments. Furthermore, to the extent that the term “include”, “have”, or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more”. Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. An apparatus comprising:
a battery;
a low voltage (LV) direct current to direct current converter (DCDC); and
a bidirectional (BiDi) switch connected with the battery and the LV DCDC.

2. The apparatus of claim 1, further comprises one or more vehicle loads.

3. The apparatus of claim 1, wherein the BiDi switch enables the battery to trickle charge when a vehicle is in a standby mode.

4. The apparatus of claim 3, wherein the BiDi switch comprises a field-effect transistor (FET) driver.

5. The apparatus of claim 4, wherein the trickle charge is for the battery and is a function of the FET driver.

6. The apparatus of claim 1, wherein the BiDi switch comprises one or more field-effect transistors (FETs) that may be opened or closed.

7. The apparatus of claim 6, wherein the one or more field-effect transistors (FETs) comprise a metal-oxide-semiconductor field-effect transistor (MOSFET).

8. The apparatus of claim 1, further comprises one or more vehicle loads, wherein the BiDi switch comprises a first metal-oxide-semiconductor field-effect transistor and a second metal-oxide-semiconductor field-effect transistor, wherein power is transmitted from the battery to the one or more vehicle loads when the first metal-oxide-semiconductor field-effect transistor and the second metal-oxide-semiconductor field-effect transistor are closed.

9. The apparatus of claim 1, wherein the battery comprises a low voltage battery.

10. The apparatus of claim 1, further comprises one or more vehicle loads, wherein the BiDi switch comprises a first metal-oxide-semiconductor field-effect transistor and a second metal-oxide-semiconductor field-effect transistor, wherein the battery is disconnected from transmitting power to the one or more vehicle loads when the first metal-oxide-semiconductor field-effect transistor and the second metal-oxide-semiconductor field-effect transistor are open.

11. The apparatus of claim 1, further comprises one or more vehicle loads, wherein the BiDi switch comprises a first metal-oxide-semiconductor field-effect transistor and a second metal-oxide-semiconductor field-effect transistor, wherein the first metal-oxide-semiconductor field-effect transistor is open and the second metal-oxide-semiconductor field-effect transistor is closed.

12. A vehicle comprising:
a low voltage (LV) battery;
a battery management system (BMS), wherein the BMS comprises a LV direct current to direct current converter (LV DCDC); and
an electronic control unit, wherein the ECU comprises a bidirectional (BiDi) switch, wherein the BiDi switch is connected with the LV battery and the LV DCDC.

13. The vehicle of claim 12, wherein the low voltage battery is approximately 12 volts to 15 volts.

14. The vehicle of claim 12, further comprises one or more vehicle loads connected with the ECU.

15. The vehicle of claim 12, wherein the BiDi switch enables the battery to trickle charge the LV battery when a vehicle is in a standby mode.

16. The vehicle of claim 12, wherein the BiDi switch comprises a field-effect transistor (FET) driver.

17. The vehicle of claim 14, wherein the BiDi switch comprises a first metal-oxide-semiconductor field-effect transistor and a second metal-oxide-semiconductor field-effect transistor.

18. An apparatus comprising:
a vehicle ground connection;
a negative temperature coefficient (NTC) sensor;
a negative voltage sensor connection;
a negative terminal connection; and
a ground busbar, wherein the ground busbar is connected with the vehicle ground connection, the NTC sensor, the negative voltage sensor connection, and the negative terminal connection.

19. The apparatus of claim 18, wherein the NTC sensor comprises a negative temperature sense connection with an electronic control unit and a positive temperature sense connection with the electronic control unit.

20. The apparatus of claim 18, further comprising:
a low voltage battery;
a first prefuse, wherein the first prefuse is connected with a first electronic control unit;
a second prefuse, wherein the second prefuse is connected with a second electronic control unit; and
a positive busbar, wherein the positive busbar is connected with a positive terminal of the low voltage battery, the positive busbar connected with the first prefuse and the second prefuse.
